(19) United States
(12) Patent Application Publication
(10) Pub. No.: US 2025/0218856 A1
(43) Pub. Date: Jul. 3, 2025

(54) Method and Device to Reduce Epitaxial Defects Due to Contact Stress Upon a Semiconductor Wafer

(71) Applicant: Taiwan Semiconductor Manufacturing Company Limited, Hsinchu (TW)

(72) Inventors: Sih-Jie LIU, Hsinchu (TW); Yee-Chia YEO, Hsinchu (TW); Che-Fu CHIU, Hsinchu (TW); Bau-Ming WANG, Kaohsiung City (TW); Chun-Feng NIEH, Hsinchu (TW); Huicheng CHANG, Hsinchu (TW)

(21) Appl. No.: 19/082,281

(22) Filed: Mar. 18, 2025

Related U.S. Application Data
(62) Division of application No. 17/000,701, filed on Aug. 24, 2020, now Pat. No. 12,283,515.

(51) Int. Cl. H01L 21/687; C23C 16/458

(52) U.S. Cl. CPC H01L 21/68742; C23C 16/4586

(57) ABSTRACT

A method of transferring a semiconductor wafer includes lifting the semiconductor wafer with a first semiconductor wafer support device. The first semiconductor wafer support device includes lift pins configured to contact a backside surface of the semiconductor wafer. At least one of the lift pins includes a supporting pillar configured to support the semiconductor wafer and a stress-reducing element having an elastic segment. The supporting pillar has a first end and a second end, and the stress-reducing element is connected to either of them to reduce contact stress between the lift pins and the semiconductor wafer. The method includes maneuvering a transfer blade under the semiconductor wafer, lowering the lift pins of the first semiconductor wafer support device such that the semiconductor wafer is supported by the transfer blade, and transferring the semiconductor wafer from a first location to a second location with the transfer blade.

### RELATED APPLICATION

This application is a divisional of U.S. patent application Ser. No. 17/000,701 entitled “Method and Device to Reduce Epitaxial Defects Due to Contact Stress upon a Semiconductor Wafer” filed on Aug. 24, 2020, the entire content of which is hereby incorporated by reference for all purposes.

### BACKGROUND

In order to fabricate devices on a semiconductor wafer, a number of unit operations (e.g., masking, etching, deposition, implanting etc.) are performed. Semiconductor wafers may be transported from unit operation to unit operation during device fabrication. To transport the semiconductor wafers to and from each unit operation, a storage container, such as a front opening unified pod (FOUP) may be used. A robot arm may be used to load and unload semiconductor wafers into and out of the FOUP. A transfer blade attached to an articulated robot arm may be positioned under the wafer and used to lift the wafer into and out of the FOUP. As the semiconductor wafers are delivered to a unit operation, the articulated robot arm may raise the semiconductor wafer out of the FOUP and deliver the semiconductor wafer to a chuck for the unit operation. After completion of the unit operation, the robot arm loads the semiconductor wafer back into a FOUP for transport to the next unit operation.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a perspective view illustrating an electrostatic chuck with wafer support lift pins extended and supporting a semiconductor wafer in accordance with some embodiments.

FIG. 2 is a vertical cross-sectional view illustrating an electrostatic chuck with a wafer support lift pins comprising springs in accordance with some embodiments.

FIG. 3 is a close-up view illustrating the wafer support lift pins of FIG. 2 in accordance with some embodiments.

FIG. 4A is a side view illustrating another wafer support lift pins in accordance with some embodiments.

FIG. 4B is a vertical cross-sectional view of the illustrating a cross section of the wafer support lift pins illustrated in FIG. 4B in accordance with some embodiments.

FIGS. 5A-5C are side views illustrating another wafer support lift pin in accordance with some embodiments.

FIG. 6A is a plan view illustrating a semiconductor wafer transfer system in accordance with some embodiments.

FIG. 6B is a vertical cross-sectional view illustrating a cross section of the wafer transfer system of FIG. 6A along line AA′ in accordance with some embodiments.

FIG. 7 is a horizontal cross-sectional view illustrating a cross section of a cluster tool with a semiconductor wafer transfer system in accordance with some embodiments.

FIG. 8 is a flowchart illustrating a method of transferring a semiconductor wafer in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Generally, the structures and methods of the present disclosure may be used to transfer and perform unit operations on semiconductor wafers while mitigating damage to the semiconductor wafer caused by the backside lift pins during the loading and unloading of the wafer from an electrostatic chuck (ESC).

As discussed above, a semiconductor wafer may be subjected to a number of unit operations (e.g., masking, etching, deposition, implanting etc.) in order to fabricate a device on the semiconductor wafer. Semiconductor wafers may be transported from unit operation to unit operation during device fabrication. To transport the semiconductor wafers to and from each unit operation, a storage container, such as a front opening unified (or universal) pod (FOUP) may be used. Alternatively a cluster tool may allow a robotic arm to transfer the semiconductor wafer to different chambers of the cluster tool. Each chamber of the cluster tool may perform a different unit operation. A robot arm may be used to load and unload semiconductor wafers into and out of a FOUP or into and out of different chambers of the cluster tool. A transfer blade attached to an articulated robot arm may be positioned under the wafer and used to lift the semiconductor wafer. As the semiconductor wafers are delivered to a unit operation, the articulated robot arm may deliver the semiconductor wafer to the ESC for the unit operation. As the semiconductor wafer is delivered to the ESC, the semiconductor wafer is lowered on to lift pins of the ESC. The lift pins may be retracted, thus lowering the wafer on to the surface of the ESC. After completion of the unit operation, the lift pins may be raised to lift the semiconductor wafer off the surface of the ESC so that the articulated robot arm in order to allow the robot arm to load the semiconductor wafer back into a FOUP for transport to the next unit operation.

Each time the semiconductor wafer is lowered onto the lift pins as well as each time the lift pins raise the semiconductor wafer off of the ESC, damage may occur to the semiconductor wafer due to the forces exerted on the wafer by the lift pins. The damage to the semiconductor wafer may propagate into succeeding layers deposited on the front side of the semiconductor wafer. Subsequent epitaxial layers may be more sensitive to wafer damage than non-epitaxial layers. For example, epitaxial layer defects may form due to substrate lattice dislocation that occur when the lift pins impact the semiconductor wafer. Oxygen may be precipitated and the silicon oxide defects may form.

Moreover, subjecting the semiconductor wafer to elevated temperatures, such as used in deposition and ion implantation unit operations, may reduce the hardness of the wafer. As a result, the heated semiconductor wafer may be more susceptible to mechanical damage due to the repeated raising and lowering performed by the ESC lift pins.

In an embodiment, the ESC is provided with lift pins that include springs contacting the bottom end of the lift pins. When the semiconductor wafer is loaded onto and/or lifted off the ESC through the embodiment lift pins, the springs included in the lift pins may compress and absorb some of the stress that would have been imparted on to the semiconductor wafer. In another embodiment, the tips of the lift pins may be provided with an elastic cover. Similar to embodiment lift pins with springs, the elastic cover may compress and absorb some of the stress that would have been imparted on to the semiconductor wafer. In another embodiment, the lifts pins may be provided with a more rounded tip than conventional lift pins. That is, rather than the tips of the lift pins ending in a point, the tips of the lift pins may include a flattened or oblate spheroid shape. In this manner, the embodiment lift pins may provide a larger contacting surface area with the backside of the semiconductor wafer. Such a larger contacting surface area may distribute the forces imparted on the semiconductor wafer through the embodiment lift pins, thereby lowering the contact stress for a given contact force.

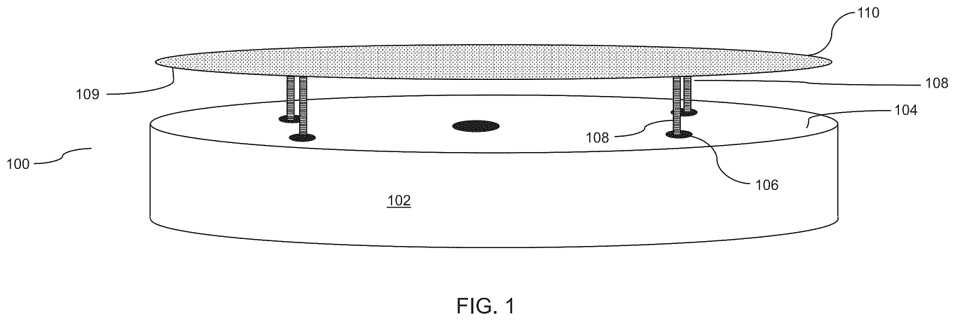

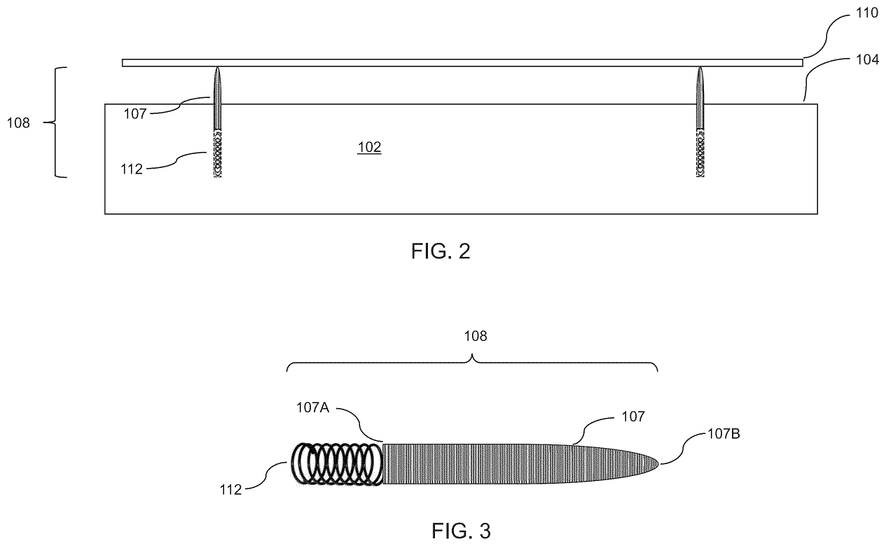

FIG. 1 is a perspective view illustrating a semiconductor wafer support device 100, such as an ESC that includes one or more stress reduction features as discussed in more detail below. The stress reduction features are configured to reduce contact stress imparted by the lift pins 108 onto the semiconductor wafer 110. The semiconductor wafer support device 100 includes a base 102 which include several holes 106 in its top surface 104. The lift pins 108 may be extended or retracted through the holes 106 in the top surface 104 of the base 102. The lift pins 108 may have an end that is configured to contact the backside surface 109 of a semiconductor wafer 110. As discussed in more detail below with reference to FIGS. 2-5C, the lift pins 108 may include a supporting pillar 107 which has a first end 107A and a second end 107B. The lift pins 108 may also include a stress-reducing element. In some embodiments, the stress-reducing element may be located at the first end 107A of the supporting pillar 107 while in other embodiments, the stress-reducing element may be located at the second end 107B of the supporting pillar 107. As discussed in more detail below with reference to FIGS. 2-5C, the stress-reducing element may be an elastic segment or may be integrally formed with the supporting pillar 107.

In operation, the lift pins 108 may be extended when receiving a semiconductor wafer 110. The lift pins 108 may be subsequently retracted in order to lower the semiconductor wafer 110 to the top surface 104 of the base 102 of the semiconductor wafer support device 100. Once the semiconductor wafer 110 engages the top surface 104 of the base of the semiconductor wafer support device 100, the unit operation of the device fabrication process may be performed. After the unit operation is performed, the semiconductor wafer 110 may be raised by the lift pins 108 away from the top surface 104 of the base 102 of the semiconductor wafer support device 100 such that a transfer blade (not shown), discussed in more detail below, may be inserted to contact the backside surface 109 of the semiconductor wafer 110. Once the transfer blade engages the backside surface 109 of the semiconductor wafer 110, the semiconductor wafer 110 may be moved to the next chamber of a cluster tool or to a storage box, such as a FOUP. Unit operations may include, but are not limited to masking, deposition, etching, chemical-mechanical polishing, ion implantation, or cleaning.

FIGS. 2 and 3 illustrate embodiment lift pins 108 that provide a stress reduction feature. As illustrated in FIGS. 2 and 3, an elastic element such as a spring 112 may be disposed within the holes 106 of the base 102 of the semiconductor wafer support device 100 prior to inserting the lift pins 108 in the holes 106. As discussed above, at least one lift pin 108 may include a supporting pillar 107 and an stress-reducing element, e.g. spring 112. The supporting pillar 107 may be configured to support the semiconductor wafer 110. The stress-reducing element, spring 112 in this embodiment, connects to the first end 107A of the supporting pillar 107 to reduce contact stress between the lift pins 108 and the semiconductor wafer 110. In an alternative embodiment, springs 112 may be integrally formed with the lift pin 108. In still a further alternative embodiment, the springs 112 may be dimensioned to insert into a recessed cavity (not shown) formed in the first end 107A of the supporting pillar 107. In still another alternative embodiment, the spring 112 may be integrally formed with a bottom surface of the hole 106 and configured to contact a first end 107A of the supporting pillar 107 of the lift pin 108.

A semiconductor wafer 110 may be placed on the lift pins 108 (or the lift pins 108 may be used to raise the semiconductor wafer 110 off the top surface 104 of the base 102 of the semiconductor wafer support device 100). In the embodiment lift pin 108 shown in FIGS. 2 and 3, the springs 112 may compress and thereby absorb some of the contact stress due to weight of the semiconductor wafer 110. In an embodiment, the springs 112 have a lateral spring constant in the range of 7-8×10³ kg/mm² and a longitudinal spring constant in the range of 19-21×10³ kg/mm², although greater or lesser spring constants may be used in various embodiments of the present disclosure. The spring constant may vary based on the material used to form the spring. Different materials may possess a different shear modulus value. In addition, the coiling of the spring 112 may impact the spring constant. The force, F, that a spring 112 may absorb may be determined by the equation:

$$F = - k x$$

where k is the spring constant and x is the spring displacement amount.

In both instances where the semiconductor wafer 110 is placed down on the lift pins 108 or raised up off the ESC by raising the lift pins 108, the springs 112 may act as a buffer to absorb contact stress and mitigate the damage to the semiconductor wafer 110. For example, a mechanical contact force that exceeds 5.1 gigapascal (GPa) may induce semiconductor wafer 110 damage. By providing the springs 112, contact stress may be absorbed and the damage to the semiconductor wafer 110 may be mitigated.

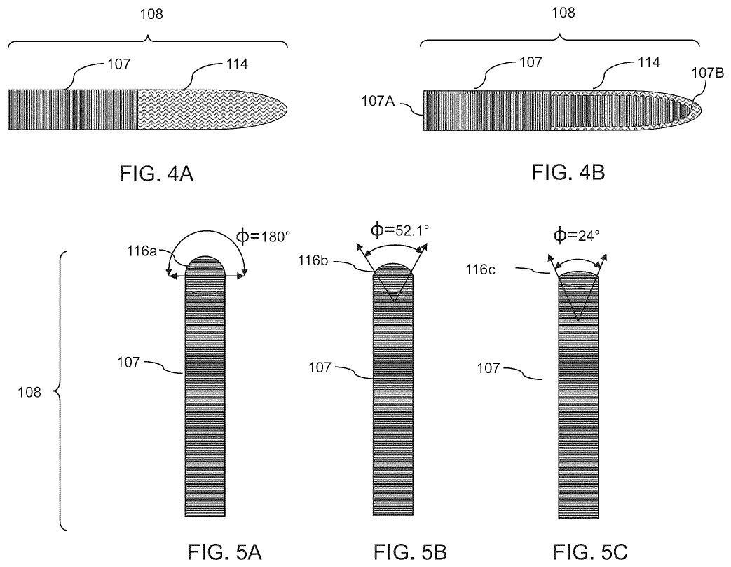

FIG. 4A is a side view of another embodiment lift pin 108 while FIG. 4B is a cross-sectional view of the embodiment lift pin 18 illustrated in FIG. 4A. The embodiment lift pin 108 illustrated in FIGS. 4A and 4B may include another stress reduction element. The stress-reducing element in this embodiment includes an elastic segment, such as an elastic cover 114. In these embodiments, an elastic cover 114 may be disposed over the second end 107B of the supporting pillar 107 of the lift pin 108. A semiconductor wafer 110 may be placed on the elastic cover 114 of the lift pins 108 (or the lift pins 108 are used to raise the semiconductor wafer 110 off the top surface 104 of the semiconductor wafer support device 100). In the embodiment lift pin 108 shown in FIGS. 4A-5C, the elastic cover 114 may compress and thereby absorb at least a portion of the contact stress imparted upon the semiconductor wafer 110 due to weight of the semiconductor wafer 110. In some embodiments, the material used to form the elastic cover 114 may vary in elastic modulus in a direction perpendicular to a major axis of the lift pins 108. In an embodiment, portions of the elastic cover 114 distal to the surface the supporting pillars 107 may have an elastic modulus greater than portions of the elastic cover 114 proximal from the surface of the supporting pillars 107. In some embodiments, elastic cover 114 may be made of a porous material. The elastic modulus may be varied by varying the amount of porosity in the elastic cover 114, with more porosity typically resulting in a lower elastic modulus. In an embodiment the elastic modulus of the elastic cover 114 may be in a range of 50-140 GPa, although materials with greater or lesser elastic modulus may be used.

The amount of contact force, i.e. the amount of force imparted to the semiconductor wafer 110 by the lift pins 108, that may be reduced by using the elastic cover may be determined using Equation 1.

$${σ}_{C} ( {F}_{N} , {D}_{0} , {E}_{e f f} ) = 0.4 * {[ \frac{{F}_{N} {E}_{eff}^{2}}{{( \frac{{D}_{0}}{2} )}^{2}} ]}^{1 / 3} \qquad Equation 1$$

Further the effective modulus, E_{eff}, may be determined using Equation 2:

$${E}_{e f f} ( {E}_{1} , {v}_{1} , {E}_{2} , {v}_{2} ) = 2 * ( \frac{1 - {v}_{1}^{2}}{{E}_{1}} + \frac{1 - {v}_{2}^{2}}{{E}_{2}} ) - 1 \qquad Equation 2$$

Where F_{N}: is the normal force; D₀: is the diameter of the lift pin 108; E_{eff}: is the effective modulus; v: is the Poisson ratio; and Eₙ is the Young's modulus of the semiconductor wafer 110 and the elastic cover 114 of the lift pins 108. The normal force F_{N} is the force to lift the semiconductor wafer 110.

The Poisson ratio of a material is a measure of the expansion or contraction of a material in a direction perpendicular to the direction of loading. The Young's modulus of a material is a measure of the amount of stress to cause a particular strain in a material. That is, the Young's modulus is a measure of stiffness. The higher the Young's modulus, the stiffer the material. The Poisson ratio and the Young's modulus are properties of the selected materials of the semiconductor wafer 110 and the elastic cover 114 of the lift pins 108.

As can be seen in Equation 1 above, the contact force σ_{c} that may be reduced by various embodiment stress reduction features may be directly proportional to the normal force F_{N} and the effective modulus E_{eff} and inversely proportion to the diameter Do of the lift pins 108. Thus, the contact force σ_{c} may be reduced by lowering the normal force F_{N} and/or the effective modulus E_{eff} and/or by increasing the diameter Do of the lift pins 108. As can be seen in Equation 2 above, the effective modulus E_{eff} is weakly proportional, i.e. varying as (1−v²), to the Poisson ratio v₁, v₂ of the semiconductor wafer 110 and the elastic cover 114 of the lift pins 108 and inversely proportional to the Young's modulus E₁, E₂ of the semiconductor wafer 110 and the elastic cover 114 of the lift pins 108. Thus, a change in the Poisson ratios will have a small effect on the effective modulus E_{eff} while an increase in the Young's modulus will lower the effective modulus E_{eff}.

FIGS. 5A-5C are side views of another embodiment lift pin 108. The embodiment lift pins 108 illustrated in FIGS. 5A-5C may include additional stress reduction features. The stress-reducing element can be integrally formed with the supporting pillar 107. In various embodiments, the diameter of the supporting pillar 107 of the lift pin 108 may be in the range of 2-10 mm. However, the diameter of the supporting pillars 107 may be larger or smaller as desired.

In a first aspect illustrated in FIG. 5A, a tip 116a disposed at the second end 107B of the supporting pillar 107 may be rounded/flattened relative to conventional lift pins. The tips 116A may be spherical in shape or slightly flattened into an oblate spheroid shape. As illustrated in FIG. 5A, in embodiments in which the tip 116a is essentially spherical, the spherical angle is essentially 180 degrees. Thus, the radius of curvature of such an embodiment tip 116a may be the same radius as the supporting pillar 107. For example, if the diameter of the supporting pillar 107 is 4 mm, the radius is 2 mm. Using a tip as shown in FIG. 5A, the radius of curvature of the tip 116a is also 2 mm and the spherical angle is essentially 180 degrees. Thus, in such an embodiment, the radius of curvature of the tip 116b may be the same (1:1) as the radius of the supporting pillar 107.

In a second aspect illustrated in FIG. 5B, a tip 116b disposed at the second end 107B of the supporting pillar 107 may have a greater flattening than the embodiment tip 116a illustrated in FIG. 5A. In embodiments as illustrated in FIG. 5B, the lift pin 108 may be configured with a tip 116b that may be described as an oblate spheroid or ellipsoid in shape. For example, the radius of curvature of the tip 116b may be twice the radius of the supporting pillar 107 of the lift pin 108, resulting in a spherical angle φ of approximately 52.1 degrees. In an example lift pin 108 in which the diameter of the supporting pillar 107 is 4 mm and the radius of the supporting pillar is 2 mm, the tip 116b as shown in FIG. 5B may have a radius of curvature of 4 mm and the spherical angle of approximately 52.1 degrees. Thus, in such an embodiment, the radius of curvature of the tip 116b may be twice (2:1) the radius of the supporting pillar 107.

In a third aspect illustrated in FIG. 5C, a tip 116c disposed at the second end 107B of the supporting pillar 107 may have yet even a greater flattening than the embodiment tip 116a illustrated in FIG. 5A and embodiment tip 116b of FIG. 5B. That is, the tips 116c has an even larger spherical angle q. In an embodiment, the radius of curvature may be 5 times the radius of supporting pillar 107 of the lift pin 108, resulting in a spherical angle φ of approximately 24 degrees. In an example lift pin 108 in which the diameter of the supporting pillar 107 is 4 mm and the radius of the supporting pillar is 2 mm, the tip 116c as shown in FIG. 5C may have a radius of curvature of 10 mm and the spherical angle of approximately 24 degrees. Thus, in such an embodiment, the radius of curvature of the tip 116c may be five times (5:1) the radius of the supporting pillar 107.

In various embodiments, the radius of curvature of the tips 116a-116c may be in the range of 1-5 times the radius of the supporting pillar 107 of the lift pins 108. Put another way, the ratio of the radius of curvature of the tips 116a-116c as compared to the radius of the supporting pillar 107 of the lift pins 108 may be (1:1) to (5:1). However, the radius of curvature of the tips 116a-116c may be larger or smaller as desired. Alternatively, the tips 116a-116c may be described in terms of spherical angle q. In various embodiments, the spherical angle φ of the tips 116a-116c may be in the range of 24-180 degrees. For example, the tip may be provided with a spherical angle φ in the range of 50-180 degrees. Moreover, the tip may be provided with a spherical angle φ in the range of 90-180 degrees. By providing a more flattened pin tip 116C (i.e., smaller spherical angle q), the surface area of the tip (116a-c) disposed on the supporting pillar 107 of the lift pin 108 may be increased. The increased surface may distribute the force imparted upon the semiconductor wafer 110 over a larger surface area, thus reducing the contact stress.

The amount of contact force that may be reduced by using the elastic cover may be determined using Equation 1, where the flattened tips 116a-116c may vary the value of the diameter of the lift pin 108, Do.

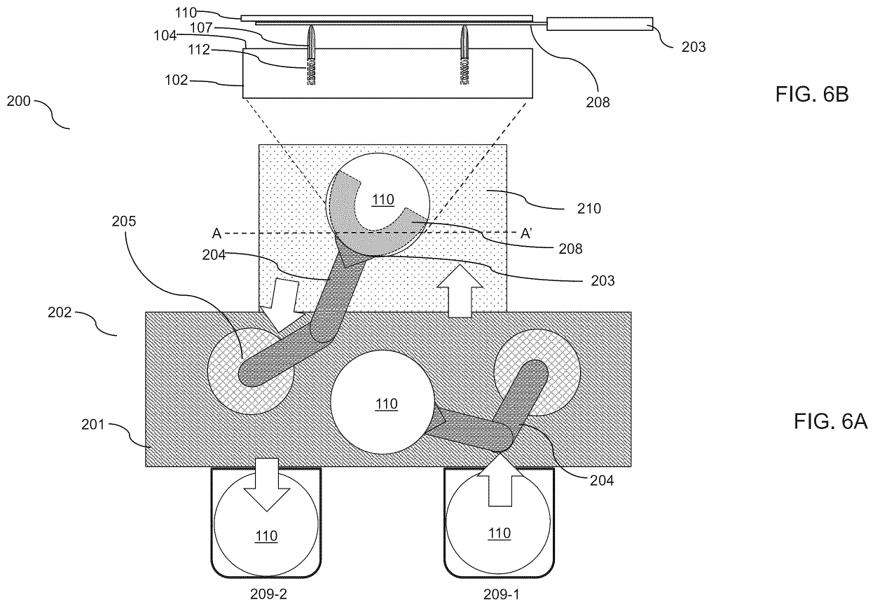

FIGS. 6A and 6B illustrates a semiconductor wafer processing system 200 according to various embodiments. The semiconductor wafer processing system 200 incudes a semiconductor wafer transfer apparatus 202 which includes at least one articulated robot arm 204. A first end 203 of the articulated robot art 204 includes a transfer blade 208 while a second end 205 is rotatably connected to a housing 201. The articulated robot arm 204 may be configured so that it may rotate and translate to more easily transfer the semiconductor wafers 110. The transfer blade 208 may be configured to lift and support a semiconductor wafer 110 during transfer of the semiconductor wafer 110 from a first FOUP 209-1 to a unit operation 210 in a semiconductor fabrication process. The unit operation may be, but is not limited to masking, deposition, etching, chemical-mechanical polishing (CMP), ion implantation, or cleaning, etc. After performing the desired unit operation processing step, the semiconductor wafer 110 may be removed from the unit operation by the same or a different articulated robot arm 204. In one aspect, the semiconductor wafer 110 may be transferred to a second FOUP 209-2. The second FOUP 209-2 may be carried, by hand or mechanically via a rail system (not shown), to the next unit operation 210. In another aspect, the semiconductor wafer processing system 200 may be part of a cluster tool (not shown) that includes several unit operations 210 in a cluster. In this aspect, the semiconductor wafer transfer apparatus 202 may transfer the semiconductor wafer 110 from one unit operation 210 to the next unit operation 210 within the same cluster without using a FOUP.

As illustrated in FIG. 6B, a semiconductor wafer 110 supported on the transfer blade 208 of the wafer transfer apparatus 202 may be maneuvered so that the semiconductor wafer 110 is located over the lift pins 108 of a semiconductor wafer support device 100, such as an ESC, associated with the unit operation 210. The lift pins 108 may be raised to support the semiconductor wafer 110. Once the semiconductor wafer 110 is supported by the lift pins 108 the transfer blade 208 may be removed. The lift pins 108 may include any of the stress reduction features disclosed with reference to FIGS. 2-5C. FIG. 6B illustrates, for example, the springs 112 disposed with the lift pins 108. The semiconductor wafer 110 may then be lowered to the top surface 104 of the semiconductor wafer support device 100 (e.g., ESC).

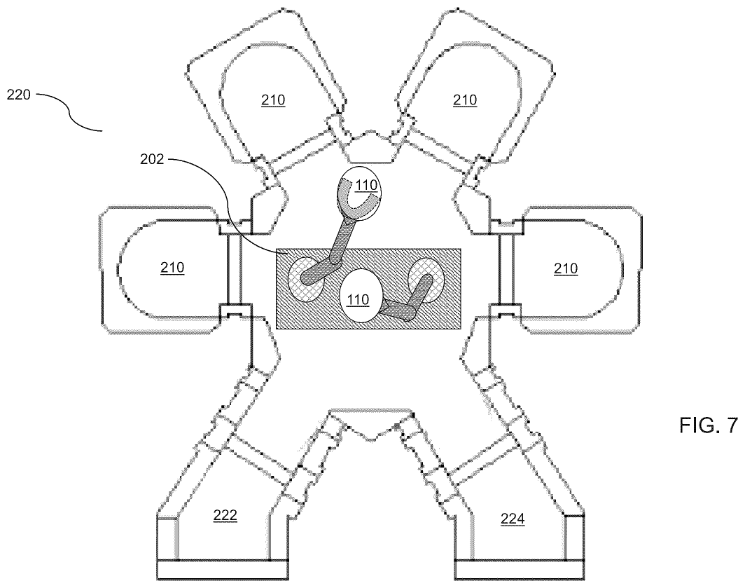

FIG. 7 illustrates a cluster tool 220 which includes a wafer transfer apparatus 202 as discussed above. As illustrated, the cluster tool 220 may be configured for four unit operation chambers 210. Each unit operation may occur in a unit operation chamber 210. However, the cluster tools 220 may be configured with more or fewer unit operation chambers 210. The cluster tool 220 may be configured with a separate inlet 222 and a separate outlet 224 so that unprocessed semiconductor wafers 110 may be provided to the cluster tool 220 via the separate inlet 222 and processed semiconductor wafers 110 may be removed from the cluster tool 220 via the separate outlet 224.

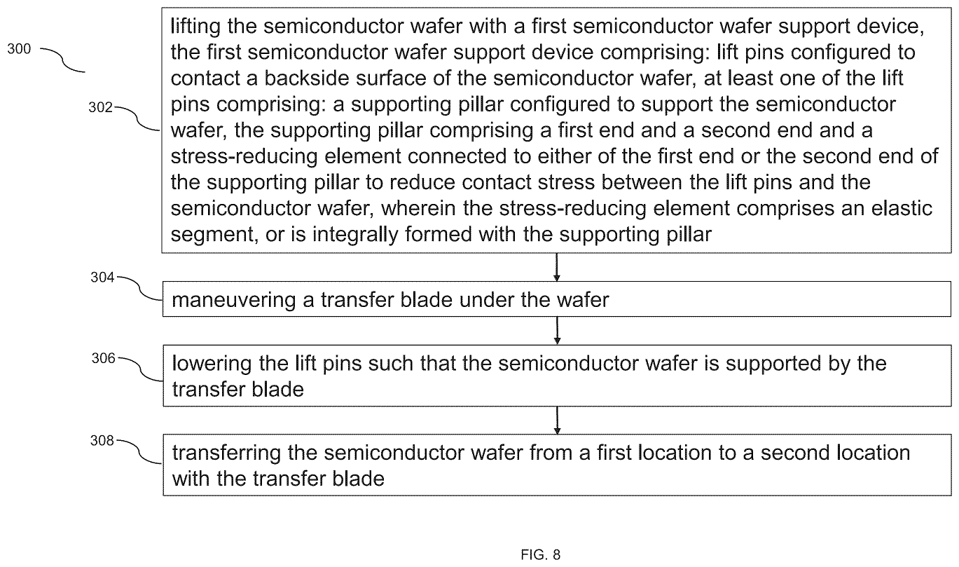

FIG. 8 is a flowchart illustrating a method 300 of transferring a semiconductor wafer 110 in accordance with some embodiments. Referring to step 302, a semiconductor wafer 110 may be lifted with a first semiconductor wafer support device 100. The first semiconductor wafer support device 100 may include lift pins 108 configured to contact a backside surface 109 of the semiconductor wafer 110. At least one of the lift pins 108 includes a supporting pillar 107 configured to support the semiconductor wafer 110. The supporting pillar 107 includes a first end 107A and a second end 107B. The lift pins 108 also include a stress-reducing element illustrated in FIGS. 2-5C (e.g., springs 112, elastic cover 114, rounded tips 116a, 116b, 116c) connected to either of the first end 107A or the second end 107B of the supporting pillar 107 to reduce contact stress between the lift pins 108 and the semiconductor wafer 110. The stress-reducing element may include an elastic segment, or is integrally formed with the supporting pillar. Referring to step 304, a transfer blade 208 may be maneuvered under the semiconductor wafer 110. Referring to step 306, the lift pins 108 may be lowered such that the semiconductor wafer 110 is supported by the transfer blade 208. Referring to step 308, the semiconductor wafer 110 may be transferred from a first location to a second location with the transfer blade 208. In some embodiments, the first location may be a first semiconductor processing unit operation 210 and the second location may be a FOUP 209-2.

In some embodiments, the semiconductor wafer 110 may be transferred from the second location to a third location. In some embodiments, the second location may be a FOUP 209-1 and the third location may be a second unit operation 210. The method may include removing the semiconductor wafer 110 from the FOUP 209-1 with the transfer blade 208, maneuvering the semiconductor wafer 110 from the FOUP 209-1 to a second semiconductor processing unit operation 210 and lifting a second semiconductor wafer support device 100 to support the semiconductor wafer 110. The second unit operation 210 may include a second semiconductor wafer support device 100 configured to support the semiconductor wafer 110. The second semiconductor wafer support device 100 may include second lift pins 108 configured to contact a backside surface 109 of the semiconductor wafer 110 and at least one second stress reduction feature illustrated in FIGS. 2-5C (e.g., springs 112, elastic cover 114, rounded tips 116a, 116b, 116c). The at least one second stress reduction feature may be configured to reduce contact stress between the second lift pins 108 and the semiconductor wafer 110. The at least one second stress reduction feature, similar to the first stress reduction feature, may include springs 112 configured to contact a first end 107a of the supporting pillar 107, an elastic cover 114 covering the first end 107A of the supporting pillar 107, the first end 107A of the supporting pillars 107 may have an oblate spheroid shape (116a-116c) or combinations thereof.

Generally, the structures and methods of the present disclosure can be used to transfer and perform unit operations 210 on semiconductor wafers 110 while mitigating damage to the semiconductor wafer 110 caused by the lift pins 108 during loading and unloading of the semiconductor wafer 110 from a semiconductor wafer support device 100, such as an ESC. The mitigation of the damage to the semiconductor wafer 110, in turn, mitigates damage propagating from the damaged semiconductor wafer into layers deposited on the semiconductor wafer, in particular epitaxial layers. In an embodiment, the semiconductor wafer support device 100 may be provided with springs 112 contacting the bottom end of the supporting pillars 107. When the semiconductor wafer 110 is loaded/lifted onto the lift pins 108, the springs 112 may compress and absorb some of the stress on the semiconductor wafer 110. In another embodiment, the tips of the lift pins 108 may be provided with an elastic cover 114. Similar to the springs 112 in the previous embodiment, the elastic cover 114 may have an elastic modulus that allows the elastic cover 114 to compress as the semiconductor wafer 110 is loaded/lifted on to the lift pins 108, thereby absorbing some of the stress on the semiconductor wafer 110. In another embodiment, the lifts pins 108 may provide a more rounded tip 116a-116c than conventional lift pins. That is, rather than the tips ending in a point, the tips of the supporting pillars of the lift pins 108 may have a flattened or oblate spheroid shape 116a-116c. In this manner, the lift pins 108 may provide a larger contacting surface area with the backside of the semiconductor wafer 110. The larger contacting surface may distribute the force imparted upon the semiconductor wafer 110 over a greater surface area, thereby lowering the contact stress for a given contact force.

An embodiment is drawn to a semiconductor wafer support device 100 including lift pins 108 configured to contact a backside surface 109 of a semiconductor wafer 110. At least one of the lift pins 108 includes a supporting pillar 107 configured to support the semiconductor wafer 110. The supporting pillar 107 includes a first end 107 A and a second end 107B. The semiconductor wafer support device 100 also includes a stress-reducing element (e.g., springs 112, elastic cover 114, rounded tips 116a, 116b, 116c) connected either of the first end 107A or the second end 107B of the supporting pillar 107 to reduce contact stress between the lift pins 108 and the semiconductor wafer 110. The stress-reducing element may include an elastic segment (e.g., springs 112, elastic cover 114) or is integrally formed with the supporting pillar (e.g., rounded tips 116a, 116b, 116c).

Another embodiment is drawn to a semiconductor wafer processing system 200 including an articulated robot arm 204 having a first end and a second end, a transfer blade 208 located at the first end of the articulated robot arm 204 and a semiconductor processing unit operation 210 comprising a semiconductor wafer support device 100. The semiconductor wafer support device 100 may include lift pins 108 configured to contact a backside surface 109 of a semiconductor wafer 110. At least one of the lift pins 108 includes a supporting pillar 107 configured to support the semiconductor wafer 110. The supporting pillar 107 includes a first end 107A and a second end 107B. The semiconductor wafer support device 100 also includes a stress-reducing element (e.g., springs 112, elastic cover 114, rounded tips 116a, 116b, 116c) connected either of the first end 107A or the second 107B of the supporting pillar 107 to reduce contact stress between the lift pins 108 and the semiconductor wafer 110. The stress-reducing element may include an elastic segment (e.g., springs 112, elastic cover 114) or is integrally formed with the supporting pillar (e.g., rounded tips 116a, 116b, 116c).

Another embodiment is drawn to a method 300 of transferring a semiconductor wafer 110 including lifting the semiconductor wafer 110 with a first semiconductor wafer support device 100. A semiconductor wafer 110 may be lifted with a first semiconductor wafer support device 100. The first semiconductor wafer support device 100 may include lift pins 108 configured to contact a backside surface 109 of the semiconductor wafer 110. At least one of the lift pins 108 includes a supporting pillar 107 configured to support the semiconductor wafer 110. The supporting pillar 107 includes a first end 107 A and a second end 107B. The lift pins 108 also include a stress-reducing element illustrated in FIGS. 2-5C (e.g., springs 112, elastic cover 114, rounded tips 116a, 116b, 116c) connected to either of the first end 107A or the second end 107B of the supporting pillar 107 to reduce contact stress between the lift pins 108 and the semiconductor wafer 110. The stress-reducing element may include an elastic segment, or is integrally formed with the supporting pillar. A transfer blade 208 may be maneuvered under the semiconductor wafer 110. The lift pins 108 may be lowered such that the semiconductor wafer 110 is supported by the transfer blade 208. Referring to step 308, the semiconductor wafer 110 may be transferred from a first location to a second location with the transfer blade 208.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of transferring a semiconductor wafer comprising:
lifting the semiconductor wafer with a first semiconductor wafer support device, the first semiconductor wafer support device comprising:
lift pins configured to contact a backside surface of the semiconductor wafer, at least one of the lift pins comprising:
a supporting pillar configured to support the semiconductor wafer, the supporting pillar comprising a first end and a second end; and
a stress-reducing element connected to either of the first end or the second end of the supporting pillar to reduce contact stress between the lift pins and the semiconductor wafer, wherein the stress-reducing element comprises an elastic segment;
maneuvering a transfer blade under the semiconductor wafer;
lowering the lift pins of the first semiconductor wafer support device such that the semiconductor wafer is supported by the transfer blade; and
transferring the semiconductor wafer from a first location to a second location with the transfer blade.

2. The method of claim 1, further comprising absorbing the contact stress by compressing springs contacting a first end of the supporting pillar.

3. The method of claim 1, further comprising absorbing the contact stress by compressing an elastic cover covering a second end of the supporting pillar.

4. The method of claim 1, wherein lifting the semiconductor wafer with the first semiconductor wafer support device comprises contacting the semiconductor wafer with lift pins having an oblate spheroid shape located at a first end of the lift pins.

5. The method of claim 1, wherein the first location comprises a first semiconductor processing unit operation and the second location comprises a front opening unified pod (FOUP).

6. The method of claim 5, further comprising transferring the semiconductor wafer from the second location to a third location by:
removing the semiconductor wafer from the FOUP with the transfer blade;
maneuvering the semiconductor wafer from the FOUP to a second semiconductor processing unit operation; and
lifting a second semiconductor wafer support device to support the semiconductor wafer, the second semiconductor wafer support device comprising:
second lift pins comprising:
a supporting pillar configured to support the semiconductor wafer, the supporting pillar comprising a first end and a second end; and
at least one stress-reducing element connected either of the first end or the second of the supporting pillar to reduce contact stress between the lift pins and the semiconductor wafer, wherein the stress-reducing element comprises an elastic segment.

7. The method of claim 6, wherein at least one second stress reduction element comprising:
a spring configured to contact the supporting pillar, wherein the spring is integrally formed with the supporting pillar and configured to absorb at least a portion of a contact stress between the first end of the lift pin and the semiconductor wafer; or
an elastic cover covering the second end of the supporting pillar, wherein the elastic cover absorbs at least a portion of the contact stress between the lift pin and the semiconductor wafer; or
the first end of the supporting pillars having an oblate spheroid shape; or
a combination thereof.

8. The method of claim 5, wherein the first semiconductor processing unit operation is configured to perform one of masking, deposition, etching, chemical-mechanical polishing (CMP), ion implantation, or cleaning.

9. A method of transferring a semiconductor wafer comprising:
maneuvering a transfer blade supporting the semiconductor wafer such that the semiconductor wafer is located over lift pins of a first semiconductor wafer support device, the first semiconductor wafer support device comprising:
lift pins configured to contact a backside surface of the semiconductor wafer, at least one of the lift pins comprising:
a supporting pillar configured to support the semiconductor wafer, the supporting pillar comprising a first end and a second end; and
a stress-reducing element connected to either of the first end or the second end of the supporting pillar to reduce contact stress between the lift pins and the semiconductor wafer, wherein the stress-reducing element comprises an elastic segment;
raising the lift pins to lift the semiconductor wafer off the transfer blade;
removing the transfer blade from under the semiconductor wafer;
lowering the lift pins to place the semiconductor wafer onto a surface of the first semiconductor wafer support device; and
transferring the semiconductor wafer from a first location to a second location with the transfer blade.

10. The method of claim 9, further comprising absorbing the contact stress by compressing springs contacting a first end of the supporting pillar.

11. The method of claim 9, wherein lifting the semiconductor wafer with the first semiconductor wafer support device comprises contacting the semiconductor wafer with lift pins having an oblate spheroid shape located at a first end of the lift pins.

12. The method of claim 9, wherein the first location comprises a first semiconductor processing unit operation and the second location comprises a front opening unified pod (FOUP).

13. The method of claim 9, further comprising transferring the semiconductor wafer from the second location to a third location by:
removing the semiconductor wafer from the FOUP with the transfer blade;
maneuvering the semiconductor wafer from the FOUP to a second semiconductor processing unit operation; and
lifting a second semiconductor wafer support device to support the semiconductor wafer, the second semiconductor wafer support device comprising:
second lift pins comprising:
a supporting pillar configured to support the semiconductor wafer, the supporting pillar comprising a first end and a second end; and
at least one stress-reducing element connected either of the first end or the second of the supporting pillar to reduce contact stress between the lift pins and the semiconductor wafer, wherein the stress-reducing element comprises an elastic segment.

14. The method of claim 9, wherein the at least one second stress reduction feature comprises:
a spring configured to contact the supporting pillar, wherein the spring is integrally formed with the supporting pillar and configured to absorb at least a portion of a contact stress between the first end of the lift pin and the semiconductor wafer; or
an elastic cover covering the second end of the supporting pillar, wherein the elastic cover absorbs at least a portion of the contact stress between the lift pin and the semiconductor wafer; or
the first end of the supporting pillars having an oblate spheroid shape; or
a combination thereof.

15. A method of transferring and performing unit operations on a semiconductor wafer comprising:
lifting the semiconductor wafer with a first electrostatic chuck at a first unit operation location, the first electrostatic chuck comprising a base and lift pins configured to reduce contact stress on the semiconductor wafer, wherein at least one of the lift pins comprises:
a supporting pillar configured to support the semiconductor wafer, the supporting pillar comprising a first end and a second end; and
a stress-reducing element connected to the supporting pillar to reduce contact stress between the lift pin and the semiconductor wafer, wherein the stress-reducing element comprises at least one elastic segment;
performing a first unit operation on the semiconductor wafer while supported on the first electrostatic chuck;
lowering the semiconductor wafer from the lift pins onto a transfer blade;
transferring the semiconductor wafer with the transfer blade to a second unit operation location;
loading the semiconductor wafer onto a second electrostatic chuck having lift pins configured to reduce contact stress on the semiconductor wafer; and
performing a second unit operation on the semiconductor wafer at the second unit operation location.

16. The method of claim 15, wherein at least one of the first unit operation or the second unit operation is configured to perform one of masking, deposition, etching, chemical-mechanical polishing (CMP), ion implantation, or cleaning.

17. The method of claim 15, wherein the stress-reducing element further comprises a spring configured to contact the first end of the supporting pillar, wherein the spring is integrally formed with the supporting pillar and configured to absorb at least a portion of a contact stress between the lift pin and the semiconductor wafer.

18. The method of claim 17, wherein the spring has a lateral spring constant in a range of 7-8×10³ kg/mm² and a longitudinal spring constant in a range of 19-21×10³ kg/mm².

19. The method of claim 15, wherein an elastic modulus of the elastic cover is in a range of 50-140 GPa.

20. The method of claim 15, further comprising transferring the semiconductor wafer between unit operations using an articulated robot arm having the transfer blade located at a first end of the articulated robot arm, wherein the articulated robot arm is configured to rotate and translate within a cluster tool.
